(19) United States
(12) Patent Application Publication
(10) Pub. No.: US 2026/0150345 A1
(43) Pub. Date: May 28, 2026

(54) TRANSISTOR AND DISPLAY APPARATUS INCLUDING THE SAME

(71) Applicant: LG Display Co., Ltd., Seoul (KR)

(72) Inventors: Jeong Yeop LEE, Paju-si (KR); Jung Seok SEO, Paju-si (KR); Kyung Chul OK, Paju-si (KR); Woo Seok JEONG, Paju-si (KR); Jong Ho KIM, Paju-si (KR)

(73) Assignee: LG Display Co., Ltd., Seoul (KR)

(21) Appl. No.: 19/345,499

(22) Filed: Sep. 30, 2025

(30) Foreign Application Priority Data
Nov. 22, 2024 (KR) 10-2024-0168386

(51) Int. Cl. H10D 30/67; H10K 59/121

(52) U.S. Cl. CPC H10D 30/6755; H10D 30/6723; H10D 30/6757; H10K 59/1213

(57) ABSTRACT

Transistors and display apparatuses including the same are disclosed herein. The transistors may include: an active layer disposed on a substrate and including an oxide semiconductor, a channel region, and first and second source-drain regions disposed at both sides of the channel region; a gate electrode disposed on the active layer and overlapping the channel region; and first and second source-drain electrodes respectively contacting the first and second source-drain regions, wherein the active layer includes a first interface layer adjacent to the gate electrode, a second interface layer adjacent to the substrate, a main layer disposed between the first interface layer and the second interface layer, and a channel control layer disposed between the main layer and the first interface layer, and wherein an indium content ratio of the channel control layer differs from an indium content ratio of each of the main layer and the first and second interface layers.

### CROSS-REFERENCE TO RELATED APPLICATIONS

This application claims the benefit of the Korean Patent Application No. 10-2024-0168386 filed on Nov. 22, 2024, which is hereby incorporated by reference as if fully set forth herein.

### BACKGROUND

### Field of the Invention

The present disclosure relates to transistors and display apparatuses including the same.

### Description of the Related Art

In televisions (TVs), monitors, smartphones, tablet personal computers (PCs), and notebook computers, display apparatuses displaying an image are being used in various modes and types.

Display apparatuses include a display panel, which includes a plurality of light emitting devices or a liquid crystal for implementing an image and a transistor for controlling an operation of each of the light emitting devices or an operation of the liquid crystal, and intactly display an image which is to be displayed through the plurality of light emitting devices or the liquid crystal.

Display apparatuses include a plurality of pixels each including a light emitting device and include a plurality of driving and switching elements for driving and controlling the light emitting device included in each of the pixels. The driving and switching elements may each be configured as a transistor.

Recently, various research and developments for enhancing the performance and reliability of transistors are being done.

### BRIEF SUMMARY

Embodiments of the present disclosure provide transistors having enhanced reliability and display apparatuses including the same.

Embodiments of the present disclosure may control the length of a channel region formed in an active layer of a transistor.

Embodiments of the present disclosure may control the distribution of an initial threshold voltage (Vth) of a transistor.

Embodiments of the present disclosure may improve a bandgap in an active layer of a transistor to prevent a carrier from being trapped.

Embodiments of the present disclosure may enhance the reliability of transistors and may decrease power consumption, thereby implementing the goals of environment, social, and governance (ESG).

Embodiments of the present disclosure include transistors having: an active layer disposed on a substrate and including an oxide semiconductor, a channel region, and first and second source-drain regions disposed at both sides of the channel region; a gate electrode disposed on the active layer and overlapping the channel region; and first and second source-drain electrodes respectively contacting the first and second source-drain regions, wherein the active layer includes a first interface layer adjacent to the gate electrode, a second interface layer adjacent to the substrate, a main layer disposed between the first interface layer and the second interface layer, and a channel control layer disposed between the main layer and the first interface layer, and wherein an indium content ratio of the channel control layer differs from an indium content ratio of each of the main layer and the first and second interface layers.

In some transistor embodiments, an indium content ratio of the main layer may be highest in the active layer, the first and second interface layers may be lower in indium content ratio than the main layer, and the channel control layer may be lower in indium content ratio than the first and second interface layers.

In some transistor embodiments, a difference of an indium content ratio between the main layer and the first interface layer may be greater than a difference of an indium content ratio between the first interface layer and the channel control layer.

In some transistor embodiments, a gallium content ratio of the main layer may be lowest in the active layer, the first and second interface layers may be higher in gallium content ratio than the main layer, and a gallium content ratio of the channel control layer may be between a gallium content ratio of the main layer and a gallium content ratio of each of the first and second interface layers.

In some transistor embodiments, a difference of a gallium content ratio between the channel control layer and the main layer may be greater than a difference of a gallium content ratio between the first interface layer and the channel control layer.

In some transistor embodiments, a zinc content ratio of the main layer may be lowest in the active layer, the first and second interface layers may be higher in zinc content ratio than the main layer, and the channel control layer may be higher in zinc content ratio than the first and second interface layers.

In some transistor embodiments, in the channel control layer, an indium content ratio may be lower than each of a gallium content ratio and a zinc content ratio.

In some transistor embodiments, an energy bandgap of the main layer may be less than an energy bandgap of each of the first and second interface layers and the channel control layer.

In some transistor embodiments, an energy bandgap difference between the channel control layer and the main layer may be greater than an energy bandgap difference between the channel control layer and the first interface layer.

In some transistor embodiments, the transistor may further include a gate insulation layer disposed between the gate electrode and the first interface layer and a buffer layer disposed between the substrate and the second interface layer.

In some transistor embodiments, the transistor may further include a light blocking pattern between the substrate and the buffer layer.

In some transistor embodiments, the light blocking pattern may contact the gate electrode.

In some transistor embodiments, the light blocking pattern may be electrically connected to one of the first and second source-drain electrodes.

Embodiments of the present disclosure also include display apparatuses having: a substrate; an active layer disposed on the substrate and including an oxide semiconductor, a channel region, and first and second source-drain regions disposed at both sides of the channel region; a gate electrode disposed on the active layer and overlapping the channel region; and first and second source-drain electrodes respectively contacting the first and second source-drain regions, wherein the active layer includes a first interface layer adjacent to the gate electrode, a second interface layer adjacent to the substrate, a main layer disposed between the first interface layer and the second interface layer, and a channel control layer disposed between the main layer and the first interface layer, and wherein an indium content ratio of the channel control layer differs from an indium content ratio of each of the main layer and the first and second interface layers.

In some display apparatus embodiments, an indium content ratio of the main layer may be highest in the active layer, the first and second interface layers may be lower in indium content ratio than the main layer, and the channel control layer may be lower in indium content ratio than the first and second interface layers.

In some display apparatus embodiments, a difference of an indium content ratio between the main layer and the first interface layer may be greater than a difference of an indium content ratio between the first interface layer and the channel control layer.

In some display apparatus embodiments, a gallium content ratio of the main layer may be lowest in the active layer, the first and second interface layers may be higher in gallium content ratio than the main layer, and a gallium content ratio of the channel control layer may be between a gallium content ratio of the main layer and a gallium content ratio of each of the first and second interface layers.

In some display apparatus embodiments, a difference of a gallium content ratio between the channel control layer and the main layer may be greater than a difference of a gallium content ratio between the first interface layer and the channel control layer.

In some display apparatus embodiments, an energy bandgap of the main layer may be less than an energy bandgap of each of the first and second interface layers and the channel control layer.

In some display apparatus embodiments, an energy bandgap difference between the channel control layer and the main layer may be greater than an energy bandgap difference between the channel control layer and the first interface layer.

In some embodiments, the display apparatus may further include a gate insulation layer disposed between the gate electrode and the first interface layer and a buffer layer disposed between the substrate and the second interface layer.

In some embodiments, the display apparatus may further include a light blocking pattern between the substrate and the buffer layer.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram for describing an embodiment of a display apparatus applicable to the present disclosure;

FIG. 2 is a diagram for describing an embodiment of a circuit diagram of a subpixel applicable to a display apparatus according to the present disclosure;

FIG. 3 is a diagram for describing an embodiment of a transistor included in a subpixel in a display apparatus according to the present disclosure;

FIG. 4 is a diagram for describing an embodiment of a channel region and first and second source-drain regions of the transistor illustrated in FIG. 3;

FIG. 5 is a diagram for describing an embodiment of an indium (In) content ratio of an active layer illustrated in FIG. 3;

FIG. 6 is a diagram for describing an embodiment of a gallium (Ga) content ratio of the active layer illustrated in FIG. 3;

FIG. 7 is a diagram for describing an embodiment of a zinc (Zn) content ratio of the active layer illustrated in FIG. 3;

FIG. 8 is a diagram for describing an energy bandgap structure of the active layer illustrated in FIG. 3;

FIG. 9 is a diagram for describing an embodiment of a switching transistor applicable to a display apparatus according to the present disclosure;

FIG. 10 is a diagram for describing an embodiment of a driving transistor applicable to a display apparatus according to the present disclosure; and

FIG. 11 is a diagram for describing an embodiment where the switching transistor and the driving transistor respectively illustrated in FIGS. 9 and 10 are applied to a display apparatus.

### DETAILED DESCRIPTION

Hereinafter, embodiments will be described in detail with reference to the accompanying drawings.

Like reference numerals refer to like elements. Also, a thickness, a ratio, and a dimension of each element described herein are illustrated to be partially enlarged or reduced for convenience of effective description. A scale of each element illustrated in the drawings of the present disclosure may have a scale which differs from a real scale, for convenience of description, but is not limited to a scale illustrated in the drawings.

In the present disclosure, when an arbitrary element (or a region, a layer, a portion, etc.) is described as “being on”, “connected”, or “coupled”, this may denote that the arbitrary element may be directly connected/coupled to another element, or a third element may be disposed therebetween.

The term “and/or” may include all of one or more combinations capable of being defined by relevant elements.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. The terms of a singular form may include plural forms unless referred to the contrary.

The terms “under”, “below”, “on”, and “above” may be used to describe a correlation between elements illustrated in the drawings. The terms may be a relative concept and may be described with respect to a direction illustrated in the drawings. For example, unless “just” or “direct” is used, one or more other elements between two elements may be disposed. Spatially relative terms “below”, “beneath”, “lower”, “above”, and “upper” may be used herein for easily describing a relationship between one device or elements and other devices or elements as illustrated in the drawings. Therefore, for example, “under” and “lower” may be opposite to “on” and “upper” with respect to a first element.

It should be understood that spatially relative terms are terms including different orientations of elements in use or operation, in addition to the orientation illustrated in the drawings. For example, if a device in the drawings is turned over, elements described as being on the “below” or “beneath” sides of other elements may be placed on “above” sides of the other elements. Therefore, the exemplary term “lower” may include both orientations of “lower” and “upper”. Likewise, the exemplary term “above” or “upper” may include both orientations of above and below.

It should be understood that the meaning of “include,” “comprise,” “including,” or “comprising,” specifies a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to an embodiment of the present disclosure will be described with reference to the accompanying drawings.

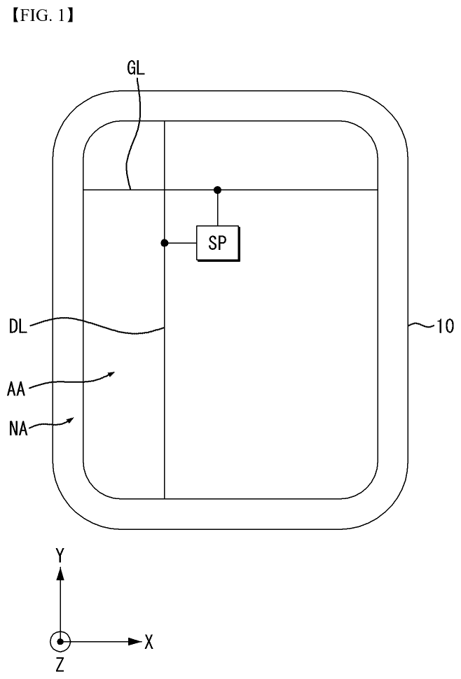

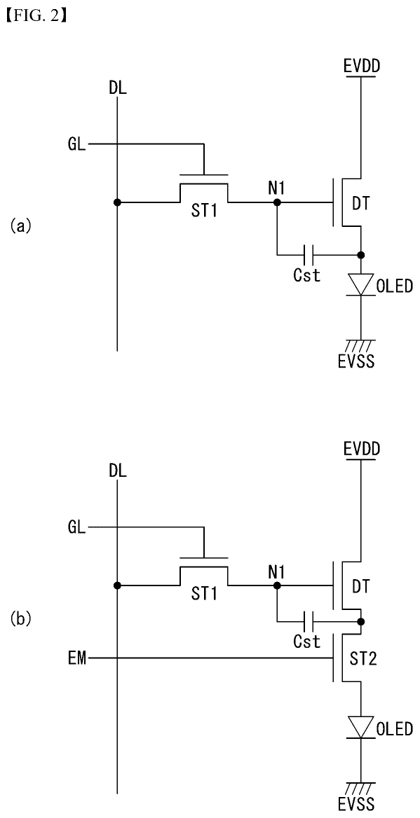

FIG. 1 is a diagram for describing an embodiment of a display apparatus applicable to the present disclosure, and FIG. 2 is a diagram for describing an embodiment of a circuit diagram of a subpixel SP applicable to a display apparatus according to the present disclosure.

Referring to FIGS. 1 and 2, a display apparatus according to an embodiment of the present disclosure may include a display panel 10, and the display panel 10 may include an active area AA and a non-active area NA.

The active area AA may be an area which displays an image. A plurality of subpixels SP may be disposed in the active area AA, and the active area AA may display an image by using the plurality of subpixels SP. An area where the plurality of subpixels SP are disposed may be the active area AA, and an area other than the active area AA may be the non-active area NA.

The non-active area NA may be disposed in an edge region surrounding the active area AA which displays an image. At least one driver for driving the plurality of subpixels SP may be disposed in the non-active area NA. The driver may be implemented as a gate-in-panel (GIP) type.

Various additional elements for driving the subpixels SP of the active area AA may be further disposed in the non-active area NA.

At least one subpixel SP among the plurality of subpixels SP, for example, as illustrated in FIG. 2 (a) or (b), may include a first switching transistor ST1, a driving transistor DT, a capacitor Cst, and a light emitting device OLED.

A first electrode (for example, a drain electrode) of the first switching transistor ST1 may be electrically connected to a data line DL, a second electrode (for example, a source electrode) thereof may be electrically connected to a first node N1, and a gate electrode of the first switching transistor ST1 may be electrically connected to a gate line GL. The first switching transistor ST1 may transfer a data signal, supplied through the data line DL, to the first node N1 in response to a scan signal supplied through the gate line GL.

The capacitor Cst may be electrically connected to the first node N1 and may be charged with a voltage applied to the first node N1.

A first electrode (for example, a drain electrode) of the driving transistor DT may be supplied with a high-level driving voltage EVDD, and a second electrode (for example, a source electrode) thereof may be electrically connected to a first electrode (for example, an anode electrode) of the light emitting device OLED. The driving transistor DT may control the amount of driving current flowing in the light emitting device OLED, based on a voltage applied to a gate electrode thereof.

An active layer of the first switching transistor ST1 and/or the driving transistor DT may include oxide such as indium-gallium-zinc-oxide (IGZO), but is not limited thereto.

The light emitting device OLED may emit light corresponding to the driving current. The light emitting device OLED may emit light corresponding to one color of red (R), green (G), blue (B), and white.

The light emitting device OLED may include the anode electrode, an emission layer disposed on the anode electrode, and a cathode electrode supplying a common voltage. The emission layer may be implemented to emit light of the same color for each pixel, like white light, or may be implemented to emit lights of different colors for each subpixel SP, like red (R) light, green (G) light, or blue (B) light.

The light emitting device OLED may be a diode of a top emission type, or may be a diode of a bottom emission type.

In FIG. 2 (a), a case where the driving transistor DT is directly connected to the light emitting device OLED is illustrated for example, but the present disclosure is not limited thereto and as illustrated in FIG. 2 (b), the driving transistor DT may be connected to the light emitting device OLED through a second switching transistor ST2.

In detail, as in FIG. 2 (b), the second switching transistor ST2 may be disposed between the driving transistor DT and the light emitting device OLED, a first electrode of the second switching transistor ST2 may be connected to the driving transistor DT, and a second electrode of the second switching transistor ST2 may be electrically connected to the light emitting device OLED.

In response to an emission control signal applied to a gate electrode, the second switching transistor ST2 may control an operation of applying the driving current, generated by the driving transistor DT, to the light emitting device OLED.

Moreover, although not shown in FIG. 2 (a) and (b), a compensation circuit (not shown) for compensating for a threshold voltage of the driving transistor DT may be further included in the subpixel SP of FIG. 1. The compensation circuit may include at least one transistor connected to the driving transistor DT and may be provided in the subpixel SP of FIG. 1.

Based on a configuration type, the compensation circuit may have a 3T1C structure where three transistors and one capacitor Cst are included in the subpixel SP of FIG. 1, or a 4T2C structure where four transistors and two capacitors Cst are included in the subpixel SP of FIG. 1, or various structures such as 5T2C, 6T1C, 6T2C, 7T1C, and 7T2C.

Furthermore, when a channel region included in an active layer has a sufficient length, each transistor configuring a circuit of a subpixel illustrated in FIG. 2 may be stably driven.

Here, a length of a channel region may be determined by a conductivity-providing process, an inorganic insulation layer deposition process, and a thermal treatment process when forming an active layer of a transistor.

When a length of a channel region is reduced, a transistor may have a characteristic where a distribution of an initial threshold voltage Vth is degraded, and due to this, the transistor may unstably operate like being turned on with a voltage which is lower than a desired threshold voltage Vth.

When an active layer of a transistor includes an oxide semiconductor so as to implement the high mobility of the transistor, a length of a channel region may be sensitively affected by an inorganic insulation layer deposition process and a thermal treatment process, and due to this, the length of the channel region may be unnecessarily reduced.

Based on a characteristic of an oxide semiconductor transistor, in the present disclosure, at least one of the switching transistor ST1 or ST2 and the driving transistor DT in the pixel circuit illustrated in FIG. 2 may include a channel control layer in an active layer, and thus, may have an appropriate channel length.

The channel control layer may have an indium (In) content ratio which is relatively lower than another semiconductor layer in the active layer and may have a high resistance characteristic.

In the present disclosure, at least one transistor may include a channel control layer and may prevent the diffusion of a conductive region in a conductivity-providing process to control an initial distribution of a threshold voltage Vth.

Moreover, a transistor including a channel control layer according to the present disclosure may be provided in a bezel region of a panel other than the pixel circuit described above and may be applied to a GIP driving circuit which supplies a scan signal to the pixel circuit.

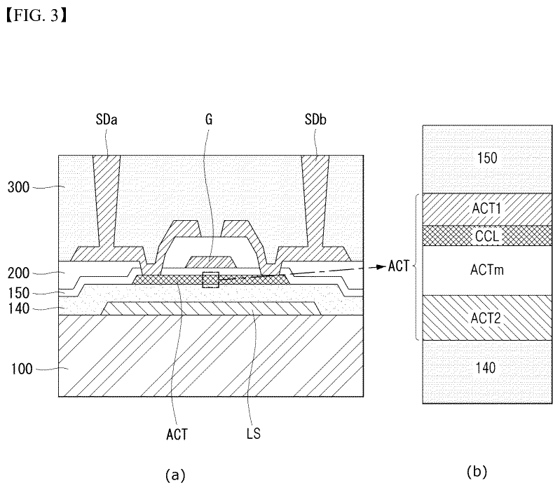

Hereinafter, an example of a transistor including a channel control layer described above with reference to FIGS. 3 to 8 will be described in detail.

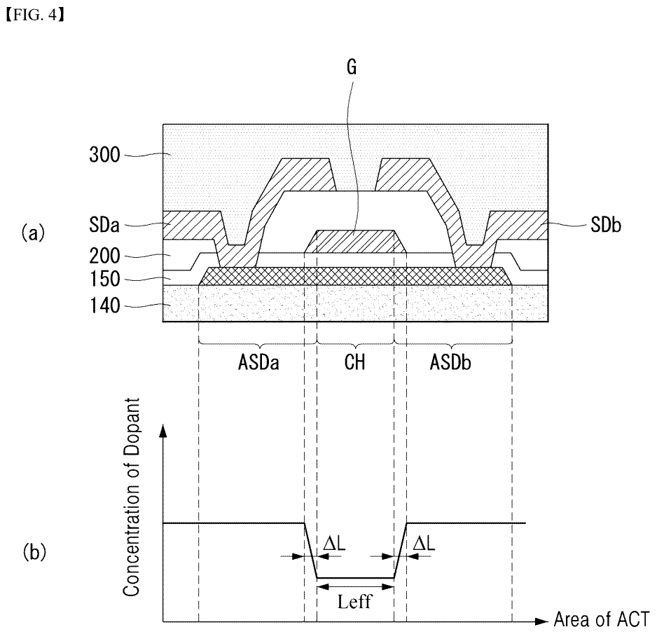

FIG. 3 is a diagram for describing an embodiment of a transistor included in a subpixel in a display apparatus according to the present disclosure, and FIG. 4 is a diagram for describing an embodiment of a channel region and first and second source-drain regions of the transistor illustrated in FIG. 3.

FIG. 3 (a) illustrates a cross-sectional view of a transistor including a substrate 100, FIG. 3 (b) is a diagram illustrating an enlarged portion of FIG. 3 (a) for describing an active layer ACT, FIG. 4 (a) illustrates a portion except a light blocking pattern LS and the substrate 100 in FIG. 3 (a), and FIG. 3 (b) is a graph illustrating a dopant concentration with respect to a region of the active layer ACT illustrated in FIG. 3 (a).

As in FIG. 3 (a), the transistor may include an active layer ACT, a gate electrode G, and first and second source-drain electrodes SDa and SDb.

As illustrated in FIG. 4, the active layer ACT may include a channel region CH and first and second source-drain regions ASDa and ASDb at both sides of the channel region CH.

The active layer ACT may be disposed on the substrate 100 and may include an oxide semiconductor and may include the first and second source-drain regions ASDa and ASDb disposed at the both sides of the channel region CH.

An oxide semiconductor material included in the active layer ACT may include, for example, at least one of InZnO (IZO)-based, InGaO (IGO)-based, InSnO (ITO)-based, InGaZnO (IGZO)-based, InGaZnSnO (IGZTO)-based, GaZnSnO (GZTO)-based, GaZnO (GZO)-based, InSnZnO (ITZO)-based, and FeInZnO (FIZO)-based oxide semiconductor materials.

The active layer ACT according to the present disclosure, as illustrated in FIG. 3 (b), may include a first interface layer ACT1, a second interface layer ACT2, a main layer ACTm, and a channel control layer CCL. A stack structure of the active layer ACT will be described in detail after the other elements except the active layer ACT illustrated in FIGS. 3 and 4 is described.

The channel region CH, as illustrated in FIG. 4 (a), may be disposed at a portion overlapping a gate electrode G, and the first and second source-drain regions ASDa and ASDb may be disposed outside the both sides of the channel region CH. The first and second source-drain regions ASDa and ASDb may include a first source-drain region ASDa disposed at one side of the channel region CH and a second source-drain region ASDb disposed at the other side of the channel region CH.

The channel region CH, as illustrated in FIG. 4 (b), may have a dopant (for example, boron (B)) concentration which is relatively lower than that of each of the first and second source-drain regions ASDa and ASDb and may have an electrical conductivity corresponding to a voltage applied to the gate electrode G, and a channel enabling a carrier to move may be formed with the voltage applied to the gate electrode G.

The first and second source-drain regions ASDa and ASDb, as illustrated in FIG. 4 (b), may have a dopant concentration which is higher than that of the channel region CH and may be a conductive region which is high in electrical conductivity. The first and second source-drain regions ASDa and ASDb may be formed by a conductivity-providing process of injecting a dopant into a portion of the active layer ACT and a subsequent thermal treatment process of forming an interlayer insulation layer 200 after the conductivity-providing process. The conductive region may be formed as the first and second source-drain regions ASDa and ASDb of the transistor.

In the channel region CH, a length of an initial channel region CH may be formed by a conductivity-providing process of injecting dopants into the active layer ACT after the gate electrode G is patterned on the active layer ACT, and some of dopants or some of hydrogen may be diffused by ΔL by a subsequent thermal treatment process, and thus, a final valid length Leff of the channel region CH may be determined. An initial distribution of a threshold voltage Vth of the transistor may be controlled based on the final valid length Leff of the channel region CH. A ΔL region, where a concentration of dopants varies in contact with the channel region CH, of the conductive region may be referred to as an offset region.

The gate electrode G may be disposed on the active layer ACT to overlap the active layer ACT. The gate electrode G may control a process of forming a channel in the channel region CH of the active layer ACT, based on a voltage applied thereto.

The gate electrode G may include a conductive material, and for example, may include metal such as aluminum (Al), chrome (Cr), copper (Cu), titanium (Ti), molybdenum (Mo), and tungsten (W).

The first and second source-drain electrodes SDa and SDb may be respectively and electrically connected to the first and second source-drain regions ASDa and ASDb. The first source-drain electrode SDa may contact the first source-drain region ASDa, and the second source-drain electrode SDb may contact the second source-drain region ASDb.

The transistor according to an embodiment of the present disclosure, as illustrated in FIG. 3 (a), may be provided on the substrate 100, the light blocking pattern LS may be provided on the substrate 100, and a buffer layer 140 may be provided on the light blocking pattern LS.

The active layer ACT may be disposed on the buffer layer 140, a gate insulation layer 150 may be disposed between the active layer ACT and the gate electrode G, the interlayer insulation layer 200 covering the gate electrode G may be disposed on the gate insulation layer 150, and the first and second source-drain electrodes SDa and SDb may pass through the interlayer insulation layer 200 and may respectively contact the first and second source-drain regions ASDa and ASDb included in the active layer ACT. The first and second source-drain electrodes SDa and SDb may be electrically connected to a driving transistor or another switching transistor or an external circuit element in a pixel circuit. The first and second source-drain electrodes SDa and SDb may be insulated from each other by an organic insulation layer such as a planarization layer 300.

The substrate 100 may be disposed in the active area AA and the non-active area NA, may be formed of a plastic material having flexibility, may have a flexible characteristic, and may include a glass material of a thin thickness having flexibility.

The substrate 100 may have a multi-layer structure including an insulating material. For example, the substrate 100 may include an insulating material and a polymer material such as polyimide (PI).

The light blocking pattern LS may be disposed on the substrate 100. In FIG. 3 (a), a case where the light blocking pattern LS is disposed just on the substrate 100 is illustrated for example, but the present disclosure is not limited thereto and another function layer may be further disposed between the light blocking pattern LS and the substrate 100.

The light blocking pattern LS may include a metal material and may block external light which passes through the substrate 100 and travels to the active layer ACT, thereby stabilizing a driving characteristic of the transistor. The light blocking pattern LS may be electrically connected to the gate electrode G or one of the first and second source-drain electrodes SDa and SDb. For example, when the transistor illustrated in FIG. 3 is a switching transistor, the light blocking pattern LS may be connected to the gate electrode G so as to enhance an operation characteristic of the transistor, and when the transistor illustrated in FIG. 3 is a driving transistor, the light blocking pattern LS may be connected to one source-drain electrode of the first and second source-drain electrodes SDa and SDb so as to enhance gray expression of the light emitting device OLED by the transistor.

The buffer layer 140 may be disposed on the substrate 100 and may be provided to cover the light blocking pattern LS. The buffer layer 140 may include an inorganic insulating material such as silicon oxide (SiO) or silicon nitride (SiN). The buffer layer 140 may insulate the light blocking pattern LS from the active layer ACT.

The gate insulation layer 150 may be disposed between the gate electrode G and the active layer ACT and may insulate the gate electrode G from the active layer ACT. The gate insulation layer 150 may include at least one of silicon oxide (SiOx), silicon nitride (SiNx), and silicon oxynitride (SiOxNy). For example, silicon oxide (SiOx) may include silicon dioxide (SiO₂).

The interlayer insulation layer 200 may be disposed on the gate insulation layer 150 to cover the gate electrode G and may extend along the gate insulation layer 150. The interlayer insulation layer 200 may include an insulating material such as silicon oxide (SiOx) or silicon oxynitride (SiOxNy).

The first and second source-drain electrodes SDa and SDb may be disposed on the interlayer insulation layer 200, and moreover, may pass through the interlayer insulation layer 200 and the gate insulation layer 150 and may electrically contact the first and second source-drain regions ASDa and ASDb.

The planarization layer 300 may include an insulating material and may be disposed on the interlayer insulation layer 200. The planarization layer 300 may remove a step height which occurs in the subpixel SP due to the transistor. An upper surface of the planarization layer 300 may include a flat surface and may include a material having high flowability. For example, the planarization layer 300 may include an organic insulating material.

Furthermore, in the transistor according to the present disclosure, as described above, the active layer ACT may include the first interface layer ACT1, the second interface layer ACT2, the main layer ACTm, and the channel control layer CCL, and the first interface layer ACT1, the second interface layer ACT2, the main layer ACTm, and the channel control layer CCL may include an oxide semiconductor.

The first interface layer ACT1 may be disposed adjacent to the gate electrode G and may be referred to as an interface active layer. For example, as in FIG. 3 (b), the first interface layer ACT1 may be disposed to contact the gate insulation layer 150, may form an energy bandgap which is higher than that of the main layer ACTm, and may have a resistivity which is higher than that of the main layer ACTm, thereby preventing some of carriers moving through the main layer ACTm from being trapped in an interface with the gate insulation layer 150 and improving the reliability of a device.

The second interface layer ACT2 may be disposed adjacent to the substrate 100 and may be referred to as a buffer active layer. For example, as in FIG. 3 (b), the second interface layer ACT2 may be disposed to contact the buffer layer 140 adjacent to the substrate 100, may form an energy bandgap which is higher than that of the main layer ACTm, and may have a resistivity which is higher than that of the main layer ACTm, thereby preventing some of carriers moving through the main layer ACTm from being trapped in an interface with the buffer layer 140 and improving the reliability of a device.

The main layer ACTm may be disposed between the first interface layer ACT1 and the second interface layer ACT2, may have a resistivity which is lower than that of each of the first and second interface layers ACT1 and ACT2 and the channel control layer CCL, and may have high mobility. The main layer ACTm may function as a channel through which a carrier moves, based on a voltage applied to the gate electrode G.

The channel control layer CCL may be disposed between the main layer ACTm and the first interface layer ACT1. The channel control layer CCL may have a resistivity which is higher than that of the main layer ACTm, may have mobility which is lower than that of the main layer ACTm, and may have an indium (In) content ratio which is lower than that of each of the first and second interface layers ACT1 and ACT2 and the main layer ACTm.

The channel control layer CCL may prevent a conductive region from being diffused by a subsequent thermal treatment process after a conductivity-providing process and may thus prevent a valid length Leff of the channel region CH from being reduced, thereby controlling an initial threshold voltage Vth distribution of a transistor.

As illustrated in FIG. 3, a thickness of the channel control layer CCL may be less than that of each of the main layer ACTm and the first and second interface layers ACT1 and ACT2. However, the present disclosure is not limited thereto.

The transistor according to an embodiment of the present disclosure may prevent a threshold voltage Vth from being shifted in a (−) direction when a length of the channel region CH is reduced, thereby more enhancing the reliability of a transistor.

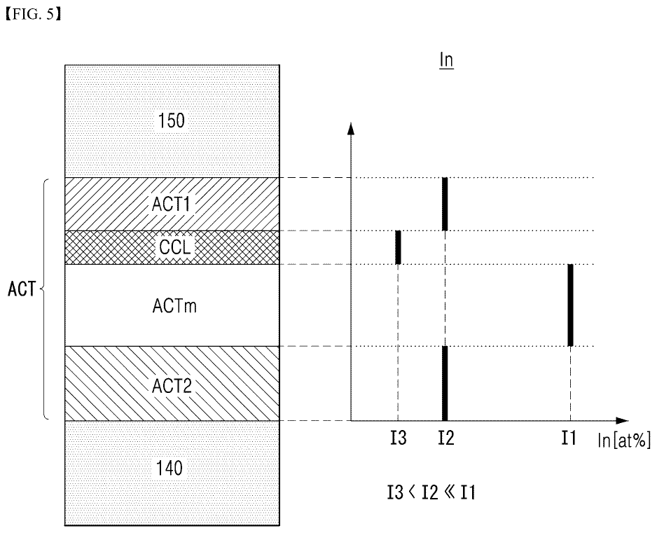

Hereinafter, a content ratio of each of indium (In), gallium (Ga), and zinc (Zn) included in the active layer ACT including the first interface layer ACT1, the second interface layer ACT2, the main layer ACTm, and the channel control layer CCL will be described with reference to FIGS. 5 to 8, and based thereon, an energy bandgap of each of the first interface layer ACT1, the second interface layer ACT2, the main layer ACTm, and the channel control layer CCL will be described.

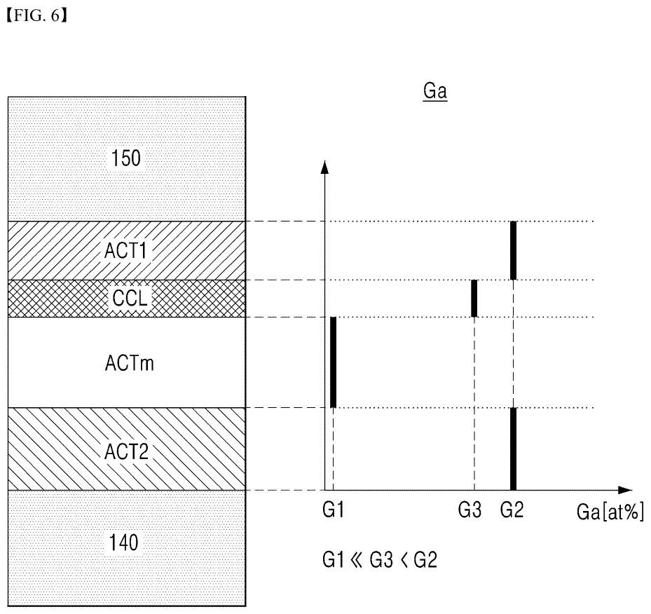

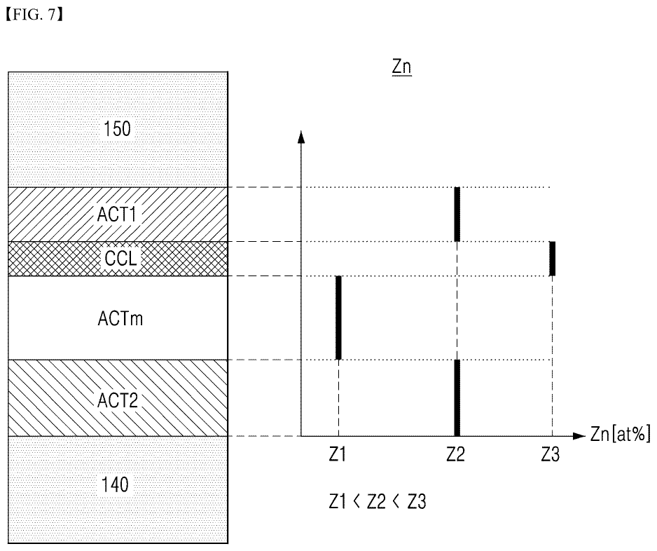

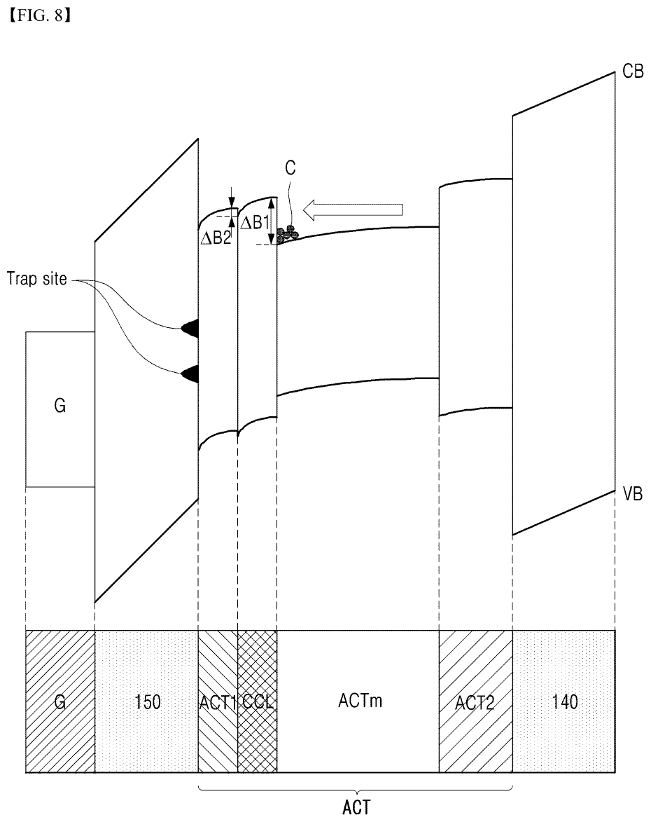

FIG. 5 is a diagram for describing an embodiment of an indium (In) content ratio of the active layer illustrated in FIG. 3, FIG. 6 is a diagram for describing an embodiment of a gallium (Ga) content ratio of the active layer illustrated in FIG. 3, FIG. 7 is a diagram for describing an embodiment of a zinc (Zn) content ratio of the active layer illustrated in FIG. 3, and FIG. 8 is a diagram for describing an energy bandgap structure of the active layer illustrated in FIG. 3.

The descriptions of FIGS. 1 to 4 above apply generally to the embodiments of FIGS. 5 to 8, and differences therebetween will be mainly described below.

An indium (In) content ratio of the active layer ACT, for example, may be configured as illustrated in FIG. 5. In detail, as in FIG. 5, in the active layer ACT, the main layer ACTm may be highest in indium (In) content ratio, the first and second interface layers ACT1 and ACT2 may be less in indium (In) content ratio than the main layer ACTm, and the channel control layer CCL may be less in indium (In) content ratio than the first and second interface layers ACT1 and ACT2.

For example, an indium content ratio of the main layer ACTm may be I1[at %], an indium content ratio of each of the first and second interface layers ACT1 and ACT2 may be I2[at %] and may be substantially equal to each other and may also be less than the indium content ratio I1 of the main layer ACTm, and an indium content ratio of the channel control layer CCL may have I3[at %] which is less than the indium content ratio I2 of each of the first and second interface layers ACT1 and ACT2.

The reason that the indium content ratio I1 of the main layer ACTm is configured to be highest in the active layer ACT may be for that a carrier mobility of the main layer ACTm is greater than a carrier mobility of the first and second interface layers ACT1 and ACT2 or the channel control layer CCL, based on that the main layer ACTm functions as a channel layer, and moreover, the reason that the indium content ratio I3 of the channel control layer CCL is configured to be lowest may be for appropriately securing a valid length Leff of the channel region CH in the main layer ACTm.

In the active layer ACT, indium (In) may affect a mobility of a carrier. That is, when a content ratio of indium increases, a mobility of a carrier may increase, and when a content ratio of indium decreases, a mobility of a carrier may decrease.

Indium may have a characteristic where an oxygen vacancy VO, which is an empty space of oxygen occurring due to a dopant injected in a conductivity-providing process of forming a conductive region, is easily generated based on a characteristic of indium, and thus, the conductive region is more easily diffused in a subsequent thermal treatment process after the conductivity-providing process.

That is, an oxide semiconductor layer such as the first and second interface layers ACT1 and ACT2 or the main layer ACTm which is high in indium content ratio may have a characteristic where a conductive region formed in a conductivity-providing process is more easily diffused in a subsequent thermal treatment process after the conductivity-providing process due to indium which is relatively high in content ratio. In this case, a conductive region may be diffused in a lower center direction of the gate electrode G, and thus, a length ΔL of an offset region may relatively increase, and the valid length Leff of the channel region CH may relatively decrease.

However, in the present disclosure, the channel control layer CCL which is relatively low in indium content ratio may be provided between the first interface layer ACT1 and the main layer ACTm, and thus, may prevent the diffusion of a conductive region in the main layer ACTm through the channel control layer CCL, thereby minimizing a length ΔL of an offset region formed in the lower center direction of the gate electrode G. Accordingly, the present disclosure may secure the valid length Leff of the channel region CH in the active layer ACT and may perform control so that an initial distribution of threshold voltage Vth of a transistor is not degraded.

An indium content ratio difference “I1-I2” between the main layer ACTm and the first interface layer ACT1 may be greater than an indium content ratio difference “I2-I3” between the first interface layer ACT1 and the channel control layer CCL. Accordingly, a channel function of the main layer ACTm may be sufficiently maintained while the channel control layer CCL is preventing the diffusion of the conductive region.

A gallium (Ga) content ratio of the active layer ACT, for example, may be configured as illustrated in FIG. 6. In detail, as in FIG. 6, the main layer ACTm may have a gallium (Ga) content ratio which is low in the active layer ACT, the first and second interface layers ACT1 and ACT2 may be higher in gallium content ratio than the main layer ACTm, and a gallium content ratio of the channel control layer CCL may be between a gallium content ratio of the main layer ACTm and a gallium content ratio of each of the first and second interface layers ACT1 and ACT2.

For example, a gallium content ratio of the main layer ACTm may be G1[at %], a gallium content ratio of each of the first and second interface layers ACT1 and ACT2 may be G2[at %], may be substantially equal to each other, and may be greater than the gallium content ratio G1 of the main layer ACTm, and a gallium content ratio G3 of the channel control layer CCL may have a value between the gallium content ratio G1 of the main layer ACTm and the gallium content ratio G2 of each of the first and second interface layers ACT1 and ACT2.

Gallium included in the active layer ACT may prevent a movement of a carrier moving through a channel formed in the main layer ACTm and may relatively largely affect an energy bandgap formed in the active layer ACT along with indium. That is, the energy bandgap formed in the active layer ACT may increase as a content ratio of indium decreases and a content ratio of gallium increases, and moreover, may decrease as a content ratio of indium increases and a content ratio of gallium decreases. An influence of zinc (Zn) on the energy bandgap of the active layer ACT may be relatively small.

Therefore, in the present disclosure, the gallium content ratio G1 of the main layer ACTm functioning as a channel may be set to be relatively low, and thus, an energy bandgap of the main layer ACTm may be relatively small, and a carrier may more smoothly move in the main layer ACTm.

Moreover, in the present disclosure, the gallium content ratio G2 of each of the first and second interface layers ACT1 and ACT2 may be set to be relatively high, and thus, an energy bandgap of each of the first and second interface layers ACT1 and ACT2 may be relatively high, and a phenomenon may be minimized where a carrier moving along the main layer ACTm is trapped between the first interface layer ACT1 and the gate insulation layer 150, thereby enhancing the reliability of a transistor.

Moreover, in the present disclosure, as the gallium content ratio G3 of the channel control layer CCL has a value between the gallium content ratio G1 of the main layer ACTm and the gallium content ratio G2 of each of the first and second interface layers ACT1 and ACT2, the energy bandgap of the channel control layer CCL may be similar to the energy bandgap of the first interface layer ACT1.

A gallium content ratio difference “G3-G1” between the channel control layer CCL and the main layer ACTm may be greater than a gallium content ratio difference “G2-G3” between the first interface layer ACT1 and the channel control layer CCL. Accordingly, an energy bandgap difference between the first interface layer ACT1 and the channel control layer CCL may be relatively small, and an energy bandgap difference between the channel control layer CCL and the main layer ACTm may be relatively large.

A zinc (Zn) content ratio of the active layer ACT, for example, may be configured as illustrated in FIG. 7. In detail, as in FIG. 7, the main layer ACTm may have a zinc content ratio which is low in the active layer ACT, the first and second interface layers ACT1 and ACT2 may be higher in zinc content ratio than the main layer ACTm, and the channel control layer CCL may be greater in zinc content ratio than the first and second interface layers ACT1 and ACT2.

For example, a zinc (Zn) content ratio of the main layer ACTm may be Z1[at %], a zinc (Zn) content ratio of each of the first and second interface layers ACT1 and ACT2 may be Z2[at %], may be substantially equal to each other, and may be greater than the zinc content ratio Z1 of the main layer ACTm, and a zinc (Zn) content ratio Z3 of the channel control layer CCL may be greater than the zinc content ratio Z2 of each of the first and second interface layers ACT1 and ACT2.

The indium content ratio I3 of the channel control layer CCL may be less than each of the gallium content ratio G3 and the zinc content ratio Z3 of the channel control layer CCL, and the gallium content ratio G3 of the channel control layer CCL may be less than the zinc content ratio Z3. Accordingly, the channel control layer CCL may prevent the diffusion of a conductive region, may form an energy bandgap similar to the first interface layer ACT1, and may increase a difference with the energy bandgap of the main layer ACTm.

The active layer ACT included in the transistor according to an embodiment of the present disclosure may have an energy bandgap diagram illustrated in FIG. 8. FIG. 8 is an energy bandgap diagram up to the gate insulation layer 150 from the buffer layer 140, and in FIG. 8, CB may denote a conduction band, and VB may denote a valence band.

An energy bandgap may decrease as a content ratio of indium increases and a content ratio of gallium decreases and may increase as a content ratio of indium decreases and a content ratio of gallium increases, and an influence of zinc (Zn) on the energy bandgap of the active layer ACT may be relatively small.

In the present disclosure, the energy bandgap of each of the first and second interface layers ACT1 and ACT2 and the channel control layer CCL may be relatively large for securing the reliability of a transistor, and the energy bandgap of the main layer ACTm may be relatively small for securing a high mobility characteristic of a transistor.

Moreover, a indium content ratio of the main layer ACTm may be relatively higher than that of each of the first and second interface layers ACT1 and ACT2 and the channel control layer CCL in order to enhance a mobility characteristic of a transistor, and a content ratio of gallium which is high in energy barrier may be relatively higher in the first and second interface layers ACT1 and ACT2 and the channel control layer CCL than the main layer ACTm in order to improve the reliability of a transistor.

Therefore, as illustrated in FIG. 8, the energy bandgap of the main layer ACTm may be lower than that of each of the first and second interface layers ACT1 and ACT2 and the channel control layer CCL. When a driving voltage is applied to the gate electrode G, band bending may occur, the main layer ACTm may form a channel through which a carrier may move, and a mobility of a transistor may be enhanced.

When a channel is formed in the main layer ACTm by a voltage applied to the gate electrode G, band bending may occur in the main layer ACTm which is high in carrier concentration, and thus, carriers C such as holes or free electrons excited to a conduction band may move in an arrow direction in the main layer ACTm and may move from the first source-drain region ASDa to the second source-drain region ASDb along the channel formed in the main layer ACTm, thereby generating a driving current.

An energy bandgap difference between the channel control layer CCL and the main layer ACTm, as illustrated in FIG. 8, may be greater than an energy bandgap difference between the channel control layer CCL and the first interface layer ACT1. Therefore, a difference ΔB1 of a conduction band formed in an interface between the channel control layer CCL and the main layer ACTm may be greater than a difference ΔB2 of a conduction band formed in an interface between the first interface layer ACT1 and the channel control layer CCL. Here, an energy bandgap difference ΔB2 between the first interface layer ACT1 and the channel control layer CCL may be substantially similar thereto.

In the present disclosure, based on that the indium content ratio I3 of the channel control layer CCL is set to be lowest in the active layer ACT, as described above, the gallium content ratio G3 of the channel control layer CCL may be set to be higher than the gallium content ratio G1 of the main layer ACTm so that an energy bandgap difference ΔB1 between the channel control layer CCL and the main layer ACTm is greater than the energy bandgap difference ΔB2 between the first interface layer ACT1 and the channel control layer CCL, and in this case, the gallium content ratio difference “G3-G1” between the channel control layer CCL and the main layer ACTm may be greater than the gallium content ratio difference “G2-G3” between the first interface layer ACT1 and the channel control layer CCL.

As described above, because the energy bandgap difference ΔB1 between the channel control layer CCL and the main layer ACTm is set to be relatively large, the present disclosure may prevent a phenomenon where the carrier C moving toward the channel control layer CCL from the main layer ACTm passes over an energy barrier of the channel control layer CCL, passes through the channel control layer CCL and the first interface layer ACT1, and moves toward the gate insulation layer 150 and may prevent a phenomenon where the carrier C is trapped in a trap site in an interface between the first interface layer ACT1 and the gate insulation layer 150. Accordingly, the reliability of a transistor may be more enhanced.

Furthermore, an energy bandgap difference between the channel control layer CCL and the main layer ACTm may be greater than an energy bandgap difference between the channel control layer CCL and the second interface layer ACT2, and thus, the reliability of a transistor may be more enhanced.

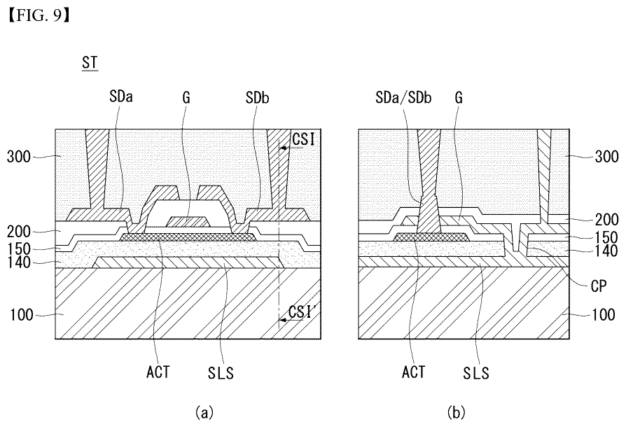

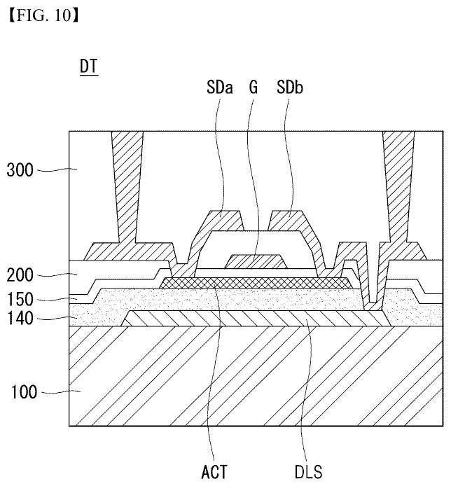

FIG. 9 is a diagram for describing an embodiment of a switching transistor applicable to a display apparatus according to the present disclosure, and FIG. 10 is a diagram for describing an embodiment of a driving transistor applicable to a display apparatus according to the present disclosure.

The descriptions of FIGS. 1 to 8 above apply generally to the embodiments of FIGS. 9 and 10, and differences therebetween will be mainly described below.

FIG. 9 (a) illustrates a cross-sectional surface of a switching transistor ST (e.g., ST1 or ST2 in FIG. 2), FIG. 9 (b) is a cross-sectional view as a cross-sectional surface taken along line CS1-CS1′ of FIG. 9 (a) is seen in an arrow direction, and FIG. 10 illustrates a cross-sectional surface of a driving transistor DT.

In each of a switching transistor ST and a driving transistor DT illustrated in FIGS. 9 and 10, as described above, an active layer ACT may include a first interface layer ACT1, a second interface layer ACT2, a main layer ACTm, and a channel control layer CCL. In each of the switching transistor ST and the driving transistor DT, a structure where a gate electrode G, a gate insulation layer 150, the active layer ACT, a buffer layer 140, and a light blocking pattern LS are provided may be the same as the above description.

As illustrated in FIG. 9, the switching transistor ST may include a first light blocking pattern SLS of a metal material between a substrate 100 and the buffer layer 140, and each of a plurality of first light blocking patterns SLS may overlap the entire active layer ACT of the switching transistor ST.

As illustrated in FIG. 10, the driving transistor DT may include a second light blocking pattern DLS of a metal material between the substrate 100 and the buffer layer 140, and each of a plurality of second light blocking patterns DLS may overlap the entire active layer ACT of the driving transistor DT.

As illustrated in FIG. 9 (a) and (b), in the switching transistor ST, the first light blocking pattern SLS may contact the gate electrode G through a connection pattern CP passing through the gate insulation layer 150 and the buffer layer 140. The connection pattern CP may include a conductive material.

As illustrated in FIG. 10, in the driving transistor DT, the second light blocking pattern DLS may be electrically connected to one of first and second source-drain electrodes SDa and SDb. In FIG. 10, a case where the second source-drain electrode SDb passes through the gate insulation layer 150 and the buffer layer 140 and contacts the second light blocking pattern DLS is illustrated for example.

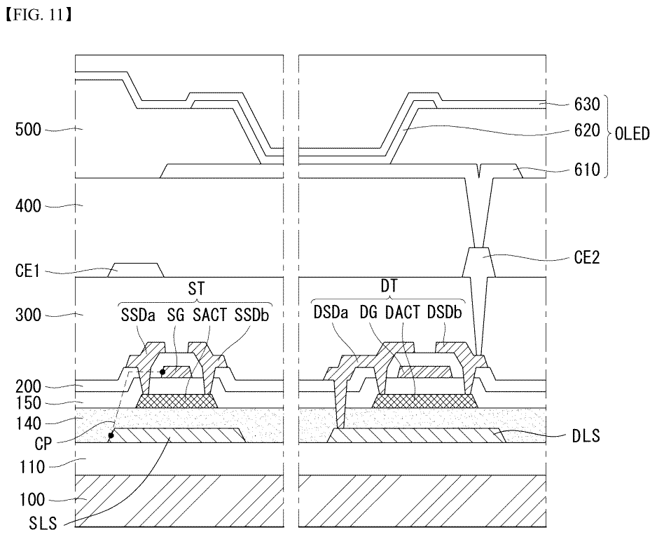

FIG. 11 is a diagram for describing an embodiment where the switching transistor ST and the driving transistor DT respectively illustrated in FIGS. 9 and 10 are applied to a display apparatus.

As illustrated in FIG. 11, a display apparatus to which a switching transistor ST and a driving transistor DT are applied may include a substrate 100, an insulation layer 110, a buffer layer 140, a switching transistor ST, a first light blocking pattern SLS, a driving transistor DT, a second light blocking pattern DLS, a gate insulation layer 150, an interlayer insulation layer 200, a first planarization layer 300, a second planarization layer 400, first and second center electrodes CE1 and CE2, a bank insulation layer 500, and a light emitting device OLED. A cross-sectional structure of the display apparatus of FIG. 11 may be an embodiment for understanding of the present disclosure, but is not limited thereto.

In each of the switching transistor ST and the driving transistor DT illustrated in FIG. 11, as described above, an active layer ACT may include a first interface layer ACT1, a second interface layer ACT2, a main layer ACTm, and a channel control layer CCL.

In FIG. 11, in the substrate 100, the buffer layer 140, the switching transistor ST, the first light blocking pattern SLS, the driving transistor DT, the second light blocking pattern DLS, the gate insulation layer 150, the interlayer insulation layer 200, and the first planarization layer 300, descriptions overlapping the above descriptions may be omitted, and a difference therebetween may be mainly described.

The substrate 100 may include a plastic material having flexibility and may have a flexible characteristic, and moreover, may include a glass material of a thin thickness having flexibility. The substrate 100 may be disposed in an active area AA and a non-active area NA of a display panel 10.

An insulation layer 110 may be disposed in an active area AA and a non-active area NA of the substrate 100. The insulation layer 110 may be referred to as a buffer layer. The insulation layer 110 may be disposed on the substrate 100, may protect structures on the substrate 100 vulnerable to water transmission from water penetrating through the substrate 100, and may planarize a surface of the substrate 100. The insulation layer 110 may be formed of an inorganic single layer, or a plurality of inorganic layers may be formed in a multi-layer structure. For example, the insulation layer 110 may include one or more inorganic layers of SiOx, SiNx, and SiOxNy.

The first light blocking pattern SLS for stabilizing a driving characteristic of the switching transistor ST and the second light blocking pattern DLS for stabilizing a driving characteristic of the driving transistor DT may be disposed on the insulation layer 110.

The buffer layer 140 may be provided on the insulation layer 110 to cover the first and second light blocking patterns LS. The buffer layer 140 may fully cover the active area AA of the substrate 100 and may include an insulating material. For example, the buffer layer 140 may include an inorganic insulating material such as SiO and SiN and may include a multi-layer structure which includes the same material or includes different materials.

The switching transistor ST and the driving transistor DT may be disposed on the buffer layer 140. As in FIG. 11, when the switching transistor ST and the driving transistor DT are disposed on the same buffer layer 140, a process may be simplified, production energy may be reduced, and the occurrence of a greenhouse gas caused by a manufacturing process may decrease, thereby implementing environment, social, and governance (ESG).

However, all switching transistors ST and driving transistors DT may not be formed on the same buffer layer 140, but the present disclosure is not limited thereto.

In detail, the switching transistor ST and the driving transistor DT may be disposed on the buffer layer 140.

The switching transistor ST may include a gate electrode SG, an active layer SACT, and first and second source-drain electrodes SSDa and SSDb, and the driving transistor DT may include a gate electrode DG, an active layer DACT, and first and second source-drain electrodes DSDa and DSDb.

The active layer SACT or DACT of at least one the switching transistor ST and the driving transistor DT, as described above, may include a first interface layer ACT1, a second interface layer ACT2, a main layer ACTm, and a channel control layer CCL and may be disposed on the buffer layer 140. The buffer layer 140 may insulate the active layer SACT of the switching transistor ST from the first light blocking layer SLS and may insulate the active layer DACT of the driving transistor DT from the second light blocking layer DLS.

The gate electrode SG of the switching transistor ST may electrically contact the first light blocking layer SLS through a connection pattern CP. Accordingly, the first light blocking layer SLS may function as a bottom gate electrode and may more enhance a reaction speed of the switching transistor ST.

One of the first and second source-drain electrodes DSDa and DSDb of the driving transistor DT may electrically contact the second light blocking pattern DLS. Accordingly, the second light blocking pattern DLS may enable the gray expression of the light emitting device OLED controlled by the driving transistor DT to be more stably controlled.

The gate insulation layer 150 may insulate the gate electrode SG and the active layer SACT of the switching transistor ST from each other and may insulate the gate electrode DG and the active layer DACT of the driving transistor DT from each other.

The interlayer insulation layer 200 may be disposed on the gate insulation layer 150 to cover the gate electrode SG of the switching transistor ST and the gate electrode DG of the driving transistor DT. The first and second source-drain electrodes SSDa and SSDb of the switching transistor ST and the first and second source-drain electrodes DSDa and DSDb of the driving transistor DT may be disposed on the interlayer insulation layer 200.

The first and second source-drain electrodes SSDa and SSDb of the switching transistor ST may pass through the interlayer insulation layer 200 and the gate insulation layer 150 and may contact first and second source-drain regions (not shown) of the switching transistor ST, and the first and second source-drain electrodes DSDa and DSDb of the driving transistor DT may pass through the interlayer insulation layer 200 and the gate insulation layer 150 and may contact first and second source-drain regions (not shown) of the driving transistor DT.

The first planarization layer 300 and the second planarization layer 400 may be sequentially stacked on the interlayer insulation layer 200 to cover the first and second source-drain electrodes SSDa and SSDb of the switching transistor ST and the first and second source-drain electrodes DSDa and DSDb of the driving transistor DT.

The first planarization layer 300 and the second planarization layer 400 may remove a step height caused by a driving circuit. An upper surface of each of the first planarization layer 300 and the second planarization layer 400 may include a flat surface, and for example, an upper surface of each of the first planarization layer 300 and the second planarization layer 400 facing the light emitting device OLED may be flat.

The first planarization layer 300 and the second planarization layer 400 may include an insulating material. The first planarization layer 300 and the second planarization layer 400 may include a material having high flowability. For example, the first planarization layer 300 and the second planarization layer 400 may include an organic insulating material. The second planarization layer 400 may include a material which differs from that of the first planarization layer 300. Accordingly, in the display apparatus according to an embodiment of the present disclosure, a step height caused by driving circuits may be effectively removed.

The first and second center electrodes CE1 and CE2 of the driving transistor DT may be disposed between the first planarization layer 300 and the second planarization layer 400. The first and second center electrodes CE1 and CE2 may include a conductive material. For example, the first and second center electrodes CE1 and CE2 may include metal such as Al, Cr, Cu, Ti, Mo, and W.

The first center electrode CE1, although not shown, may electrically connect the switching transistor ST to the driving transistor DT, or may electrically connect the switching transistor ST to another circuit element.

The second center electrode CE2 may electrically connect the driving transistor DT to the light emitting device OLED. For example, as in FIG. 11, the second center electrode CE2 may electrically connect the second source-drain electrode DSDb of the driving transistor DT to a first electrode (an anode electrode) 610 of the light emitting device OLED.

In FIG. 11, a case where the second source-drain electrode DSDb of the driving transistor DT contacts the first electrode (anode electrode) 610 of the light emitting device OLED through the second center electrode CE2 is illustrated for example, but the present disclosure is not limited thereto and as in FIG. 2 (b), when another switching transistor ST (ST2) is provided between the driving transistor DT and the light emitting device OLED, the driving transistor DT may be electrically connected to the light emitting device OLED through the other switching transistor ST.

A bank insulation layer 500 may be disposed on the second planarization layer 400.

The bank insulation layer 500 may include an insulating material. For example, the bank insulation layer 500 may include an organic insulating material. The bank insulation layer 500 may include a material which differs from that of each of the first planarization layer 300 and the second planarization layer 400. The bank insulation layer 500 may cover an edge of the first electrode 610 (for example, the anode electrode). An emission layer 620 and a second electrode 630 (for example, a cathode electrode) may be stacked on a partial region of the first electrode 610 exposed by the bank insulation layer 500. For example, the bank insulation layer 500 may define an emission region in each subpixel SP.

The light emitting device 600 may be disposed in the emission region and may include the first electrode 610, the emission layer 620, and the second electrode 630.

In the light emitting device OLED, for example, the first electrode 610 may function as the anode electrode and may include a conductive material. The first electrode 610 may have a high reflectance. For example, the first electrode 610 may include metal such as Al and silver (Ag). The first electrode 610 may have a multi-layer structure. For example, the first electrode 610 may have a structure where a reflective electrode including metal is disposed between transparent electrodes including a transparent conductive material such as indium tin oxide (ITO) or indium zinc oxide (IZO).

The emission layer 620 may generate light of luminance corresponding to a voltage difference between the first electrode 610 and the second electrode 630. For example, the emission layer 620 may include an emission material layer (EML) including an emission material. The emission material may include an organic material, an inorganic material, or a hybrid material. For example, the emission layer 620 may include an emission material layer including an organic material.

The emission layer 620 may include at least one of a first emission common layer (not shown) disposed between first electrodes 610 and a second emission common layer (not shown) disposed between second electrodes 630. Each of the first emission common layer (not shown) and the second emission common layer (not shown) may include at least one of a hole injection layer (HIL), a hole transport layer (HTL), an electron transport layer (ETL), and an electron injection layer (EIL). The emission layer 620 may emit light of one of red (R), green (G), and blue (B).

The second electrode 630, for example, may function as a cathode electrode and may include a conductive material. The second electrode 630 may include a material which differs from that of the first electrode 610. For example, the second electrode 630 may be a transparent electrode including a transparent conductive material such as ITO or IZO. The second electrode 630 may have a transmittance which is higher than that of the first electrode 610. Accordingly, in the display apparatus according to an embodiment of the present disclosure, light generated by the emission layer 620 may be emitted through the second electrode 630.

In FIG. 11, as in a pixel equivalent circuit of FIG. 2 (a), a case where the driving transistor DT is directly connected to the light emitting device OLED has been described for example, but the present disclosure is not limited thereto.

For example, as in a pixel equivalent circuit of FIG. 2 (b), the driving transistor DT may be connected to the light emitting device OLED through the switching transistor ST receiving an emission control signal. In this case, in FIG. 11, the switching transistor ST may be electrically connected to the light emitting device OLED through a center electrode.

As described above, in embodiments of the present disclosure, the channel control layer CCL of a high resistance may be provided between the first interface layer ACT1 and the main layer ACTm in the active layer ACT of the transistor included in the display apparatus, and thus, may prevent a conductive region from extending in a center direction of the active layer ACT through the channel control layer CCL in a conductivity-providing process. Accordingly, embodiments of the present disclosure may prevent the extension of the conductive region, thereby preventing a reduction in length of the channel region CH.

In embodiments of the present disclosure, a channel having an appropriate length may be secured through the channel control layer CCL which is relatively low in indium content ratio and is relatively low in mobility, and thus, an initial threshold voltage (Vth) distribution of a transistor may be secured.

In embodiments of the present disclosure, the channel control layer CCL may be provided, and thus, may enhance the reliability of a transistor and may enhance image quality, thereby implementing ESG.

Embodiments of the present disclosure may realize the following effects.

In embodiments of the present disclosure, a channel control layer of a high resistance may be provided between a first interface layer and a main layer in an active layer of a transistor included in a display apparatus, and thus, may prevent a conductive region from extending in a center direction of the active layer in a conductivity-providing process. Accordingly, embodiments of the present disclosure may prevent the extension of the conductive region, thereby preventing a reduction in length of a channel region.

In embodiments of the present disclosure, a channel having an appropriate length may be secured through a channel control layer which is relatively low in indium content ratio and is relatively low in mobility, and thus, an initial threshold voltage (Vth) distribution of a transistor may be secured.

In embodiments of the present disclosure, because an indium content ratio of a channel control layer is reduced, and a gallium content ratio thereof increases, an energy bandgap of the channel control layer may have a level similar to an energy bandgap of a first interface layer, thereby preventing a carrier from being trapped between the first interface layer and a gate insulation layer.

Embodiments of the present disclosure may enhance a low power of a transistor and may decrease the power consumption of a display apparatus, thereby implementing the goals of ESG.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transistor comprising:
an active layer disposed on a substrate and including an oxide semiconductor, a channel region, and first and second source-drain regions disposed at both sides of the channel region;
a gate electrode disposed on the active layer and overlapping the channel region; and
first and second source-drain electrodes respectively contacting the first and second source-drain regions,
wherein the active layer comprises a first interface layer adjacent to the gate electrode, a second interface layer adjacent to the substrate, a main layer disposed between the first interface layer and the second interface layer, and a channel control layer disposed between the main layer and the first interface layer, and
an indium content ratio of the channel control layer differs from an indium content ratio of each of the main layer and the first and second interface layers.

2. The transistor of claim 1, wherein an indium content ratio of the main layer is highest in the active layer,
the first and second interface layers are lower in indium content ratio than the main layer, and
the channel control layer is lower in indium content ratio than the first and second interface layers.

3. The transistor of claim 1, wherein a difference of an indium content ratio between the main layer and the first interface layer is greater than a difference of an indium content ratio between the first interface layer and the channel control layer.

4. The transistor of claim 1, wherein a gallium content ratio of the main layer is lowest in the active layer,
the first and second interface layers are higher in gallium content ratio than the main layer, and
a gallium content ratio of the channel control layer is between a gallium content ratio of the main layer and a gallium content ratio of each of the first and second interface layers.

5. The transistor of claim 1, wherein a difference of a gallium content ratio between the channel control layer and the main layer is greater than a difference of a gallium content ratio between the first interface layer and the channel control layer.

6. The transistor of claim 1, wherein a zinc content ratio of the main layer is lowest in the active layer,
the first and second interface layers are higher in zinc content ratio than the main layer, and
the channel control layer is higher in zinc content ratio than the first and second interface layers.

7. The transistor of claim 1, wherein, in the channel control layer, an indium content ratio is lower than each of a gallium content ratio and a zinc content ratio.

8. The transistor of claim 1, wherein an energy bandgap of the main layer is less than an energy bandgap of each of the first and second interface layers and the channel control layer.

9. The transistor of claim 1, wherein an energy bandgap difference between the channel control layer and the main layer is greater than an energy bandgap difference between the channel control layer and the first interface layer.

10. The transistor of claim 1, further comprising:
a gate insulation layer disposed between the gate electrode and the first interface layer; and
a buffer layer disposed between the substrate and the second interface layer.

11. The transistor of claim 10, further comprising a light blocking pattern between the substrate and the buffer layer.

12. The transistor of claim 11, wherein the light blocking pattern contacts the gate electrode.

13. The transistor of claim 11, wherein the light blocking pattern is electrically connected to one of the first and second source-drain electrodes.

14. The transistor of claim 11, wherein a thickness of the channel control layer is less than that of each of the main layer and the first interface layer and the second interface layer.

15. A display apparatus comprising:
a substrate;
an active layer disposed on the substrate and including an oxide semiconductor, a channel region, and first and second source-drain regions disposed at both sides of the channel region;
a gate electrode disposed on the active layer and overlapping the channel region; and
first and second source-drain electrodes respectively contacting the first and second source-drain regions,
wherein the active layer comprises a first interface layer adjacent to the gate electrode, a second interface layer adjacent to the substrate, a main layer disposed between the first interface layer and the second interface layer, and a channel control layer disposed between the main layer and the first interface layer, and
an indium content ratio of the channel control layer differs from an indium content ratio of each of the main layer and the first and second interface layers.

16. The display apparatus of claim 15, wherein an indium content ratio of the main layer is highest in the active layer,
the first and second interface layers are lower in indium content ratio than the main layer, and
the channel control layer is lower in indium content ratio than the first and second interface layers.

17. The display apparatus of claim 15, wherein a difference of an indium content ratio between the main layer and the first interface layer is greater than a difference of an indium content ratio between the first interface layer and the channel control layer.

18. The display apparatus of claim 15, wherein a gallium content ratio of the main layer is lowest in the active layer,
the first and second interface layers are higher in gallium content ratio than the main layer, and
a gallium content ratio of the channel control layer is between a gallium content ratio of the main layer and a gallium content ratio of each of the first and second interface layers.

19. The display apparatus of claim 15, wherein a difference of a gallium content ratio between the channel control layer and the main layer is greater than a difference of a gallium content ratio between the first interface layer and the channel control layer.

20. The display apparatus of claim 15, wherein an energy bandgap of the main layer is less than an energy bandgap of each of the first and second interface layers and the channel control layer, and
wherein an energy bandgap difference between the channel control layer and the main layer is greater than an energy bandgap difference between the channel control layer and the first interface layer.
